(19) United States
(12) Patent Application Publication
(10) Pub. No.: US 2013/0174904 A1
(43) Pub. Date: Jul. 11, 2013

(54) COMPOSITION FOR ANTIREFLECTIVE FILM FOR SOLAR CELL, ANTIREFLECTIVE FILM FOR SOLAR CELL, METHOD FOR MANUFACTURING ANTIREFLECTIVE FILM FOR SOLAR CELL, AND SOLAR CELL

(71) Applicants: Kazuhiko Yamasaki, Naka-gun (JP); Satoko Higano, Naka-gun (JP); Reiko Izumi, Naka-gun (JP); Toshiharu Hayashi, Tokyo (JP)

(72) Inventors: Kazuhiko Yamasaki, Naka-gun (JP); Satoko Higano, Naka-gun (JP); Reiko Izumi, Naka-gun (JP); Toshiharu Hayashi, Tokyo (JP)

(73) Assignee: MITSUBISHI MATERIALS CORPORATION, Tokyo (JP)

(21) Appl. No.: 13/820,897

(22) PCT Filed: Sep. 29, 2011
(86) PCT No.: PCT/JP2011/072417

§ 371 Date: Mar. 5, 2013

(30) Foreign Application Priority Data
Sep. 30, 2010 (JP) 2010-223306

(51) Int. Cl. H01L 31/0216; C09D 5/00

(52) U.S. Cl. CPC H01L 31/02168; C09D 5/00
USPC 136/256; 438/72; 106/287.19; 106/187.1; 106/287.26; 428/220

(57) ABSTRACT

This composition for an antireflective film includes a translucent binder, wherein the translucent binder contains either one or both of a polymer type binder and a non-polymer type binder, a content of the translucent binder is in a range of 10 parts by mass to 90 parts by mass with respect to 100 parts by mass of a total amount of components other than a dispersion medium, and a refractive index of an antireflective film which is formed by curing the composition for an antireflective film is in a range of 1.70 to 1.90. This method for manufacturing an antireflective film includes: applying the above-described composition for an antireflective film onto a transparent conductive film by a wet coating method to form an antireflective coating film; and curing the antireflective coating film to form an antireflective film.

### TECHNICAL FIELD

The present invention relates to a composition for an antireflective film for a solar cell, an antireflective film, a method for manufacturing an antireflective film, and a solar cell. More specifically, the present invention relates to a solar cell such as a single crystalline silicon solar cell, a polycrystalline silicon solar cell, a silicon heterojunction solar cell, or a substrate type solar cell, and the solar cell includes a transparent conductive film; an antireflective film; and a sealing material film, and particularly the present invention relates to a composition for an antireflective film for this solar cell, an antireflective film, and a method for manufacturing an antireflective film.

The present application claims priority on Japanese Patent Application No. 2010-223306 filed on Sep. 30, 2010, the content of which is incorporated herein by reference.

### BACKGROUND ART

Currently, the research, development, and practical realization for clean energy have been progressed from the standpoint of environmental protection, and solar cells have attracted attention because sunlight, which is an energy source thereof, is inexhaustible and pollution-free. In the related art, a bulk solar cell including single crystalline silicon or polycrystalline silicon is used as a solar cell.

Meanwhile, semiconductor thin film solar cells (hereinafter, referred to as thin film solar cells) including a semiconductor such as amorphous silicon are manufactured by forming a necessary amount of semiconductor layers, which are photoelectric conversion layers, on an inexpensive substrate such as glass or stainless steel. Therefore, the thin film solar cells are considered to be the mainstream of future solar cells because it is thin and light-weight, the manufacturing cost is low, and it is easy to increase its area.

In solar cells, a film is formed by a vacuum deposition method such as a sputtering method, a CVD method, or the like. However, considerable cost is required for maintaining and operating a large-sized vacuum deposition device. Therefore, in the case where a film is formed by a wet film-forming method, a significant improvement in running cost may be expected.

In either case of the bulk solar cells or the thin film solar cells, it is important to guide incident light into a photoelectric conversion layer without any loss in order to increase a power generation efficiency. Therefore, it is necessary that an amount of light reflected from a surface of the photoelectric conversion layer be reduced.

Techniques relating to an antireflective film for a solar cell are disclosed in Patent Documents 1 and 2. Patent Document 1 discloses a method for manufacturing a solar cell including; a process of forming a silicon oxide film on an impurity diffusion region of a solar cell; and a process of applying a coating material, which contains an antireflective film material, onto the silicon oxide film so as to form an antireflective film. Patent Document 2 discloses a composition for an antireflective film containing a silicon compound and an antireflective film substrate having a refractive index of 1.25 or less and a predetermined moisture resistance. In Patent Document 2, the antireflective film substrate is formed by applying the composition containing the silicon compound onto a substrate and baking the substrate at a temperature of 400° C. or higher and 450° or lower.

However, in the manufacturing method disclosed in Patent Document 1, an antireflective film having a refractive index of 1.8 to 2.3 is formed on a silicon oxide film having a refractive index of 1.40 to 1.45.

Generally, a sealing material film consisting of an ethylene vinyl acetate copolymer (EVA) and the like is formed on an antireflective film. The refractive index of EVA is in a range of 1.5 to 1.6. Therefore, when the refractive indices of films are described in order of film formation, a silicon oxide film is 1.4 to 1.45, an antireflective film is 1.8 to 2.3, and a sealing material film is 1.5 to 1.6. In the case where the antireflective film is formed in this manner, changes in refractive index are large and the amount of reflected incident sunlight increases. It is considered that, in particular, the amount of light reflected between the silicon oxide film and the antireflective film increases and the conversion efficiency of a solar cell deteriorates.

In addition, since the antireflective film substrate disclosed in Patent Document 2 is formed by applying the composition, which contains the silicon compound, onto the substrate and baking the substrate, the antireflective film is positioned on a sunlight-incident surface side of the substrate. Therefore, this antireflective film cannot be used for a bulk solar cell, a substrate type solar cell in which sunlight does not pass through asubstrate, or a silicon heterojunction solar cell. In addition, the antireflective film is formed at a temperature of 400° C. or higher; and therefore, in the case where the antireflective film is formed on a semiconductor layer, semiconductor characteristics deteriorate due to heating. Therefore, it is difficult for the antireflective film to be formed on a semiconductor layer.

### PRIOR ART DOCUMENT

### Patent Document

Patent Document 1: Japanese Unexamined Patent Application, First Publication No. 2003-179239
Patent Document 2: Japanese Unexamined Patent Application, First Publication No. 2010-65174

### DISCLOSURE OF THE INVENTION

### Problems to be Solved by the Invention

The present invention aims to provide an antireflective film which can reduce light reflected from a surface of a transparent conductive film and to provide a composition with which this antireflective film can be formed according to a wet coating method, in a solar cell such as a bulk solar cell, a silicon heterojunction solar cell, or a substrate type thin film solar cell.

### Solutions for Solving the Problems

As a result of thorough research for the conversion efficiency of a solar cell, the present inventors found that the conversion efficiency of a solar cell can be improved by forming an antireflective film having a specific refractive index between a transparent conductive film and a sealing material film. In addition, the present inventors developed a composition for an antireflective film, with which the antireflective film can be simply formed according to a wet coating method at a low cost without using high-cost equipment.

A composition for an antireflective film for a solar cell, an antireflective film, a method for manufacturing an antireflective film, and a solar cell according to an aspect of the present invention will be described below.

A composition for an antireflective film for a solar cell according to an aspect of the invention includes a translucent binder, wherein the translucent binder contains either one or both of a polymer type binder and a non-polymer type binder, a content of the translucent binder is in a range of 10 parts by mass to 90 parts by mass with respect to 100 parts by mass of a total amount of components other than a dispersion medium, and a refractive index of an antireflective film which is formed by curing the composition for an antireflective film is in a range of 1.70 to 1.90.

In the composition for an antireflective film for a solar cell according to the aspect of the invention, the polymer type binder may be at least one kind selected from a group consisting of acrylic resin, polycarbonate, polyester, alkyd resin, polyurethane, acrylic urethane, polystyrene, polyacetal, polyamide, polyvinyl alcohol, polyvinyl acetate, cellulose, and a siloxane polymer.

The translucent binder may contain the polymer type binder and at least one kind selected from a group consisting of a first metal soap, a first metal complex, a first metal alkoxide, and a hydrolysis product of a metal alkoxide. A metal included in the first metal soap, the first metal complex, the first metal alkoxide, and the hydrolysis product of a metal alkoxide may be one kind selected from a group consisting of aluminum, silicon, titanium, chromium, manganese, iron, cobalt, nickel, silver, copper, zinc, molybdenum, and tin.

The non-polymer type binder may be at least one kind selected from a group consisting of a second metal soap, a second metal complex, a second metal alkoxide, alkoxysilane, a halosilane, 2-alkoxyethanol, β-diketone, and alkyl acetate.

A metal included in the second metal soap, the second metal complex, and the second metal alkoxide may be one kind selected from a group consisting of aluminum, silicon, titanium, chromium, manganese, iron, cobalt, nickel, silver, copper, zinc, molybdenum, tin, indium, and antimony.

The non-polymer type binder may be a metal alkoxide of silicon or titanium.

The composition for an antireflective film for a solar cell may further include transparent oxide fine particles, wherein a content of the transparent oxide fine particles may be in a range of 10 parts by mass to 90 parts by mass with respect to 100 parts by mass of a total amount of components other than a dispersion medium.

The transparent oxide fine particles may be particles of at least one kind selected from a group consisting of SiO₂, TiO₂, ZrO₂, indium tin oxide, ZnO, and antimony tin oxide.

An average particle size of the transparent oxide fine particles may be in a range of 10 nm to 100 nm.

The composition for an antireflective film for a solar cell may further include a coupling agent, wherein the coupling agent may be one kind selected from a group consisting of vinyl triethoxy silane, γ-glycidoxy propyl trimethoxy silane, γ-methacryloxy propyl trimethoxy silane, an aluminum coupling agent having an acetoalkoxy group, a titanium coupling agent having a dialkyl pyrophosphoric acid group, and a titanium coupling agent having a dialkyl phosphoric acid group. A content of the coupling agent may be in a range of 0.01 parts by mass to 5 parts by mass with respect to 100 parts by mass of a total amount of components.

The composition for an antireflective film for a solar cell may further include a dispersion medium, wherein the dispersion medium may be at least one kind selected from a group consisting of water, methanol, ethanol, isopropyl alcohol, butanol, acetone, methyl ethyl ketone, cyclohexanone, isophorone, toluene, xylene, hexane, cyclohexane, N,N-dimethylformamide, N,N-dimethylacetamide, dimethyl sulfoxide, ethylene glycol, and ethyl cellosolve. A content of the dispersion medium may be in a range of 80 parts by mass to 99 parts by mass with respect to 100 parts by mass of a total amount of components.

The composition for an antireflective film for a solar cell may further include a water-soluble cellulose derivative, wherein the water-soluble cellulose derivative may be hydroxypropyl cellulose or hydroxypropyl methyl cellulose. A content of the water-soluble cellulose derivative may be in a range of 0.2 parts by mass to 5 parts by mass with respect to 100 parts by mass of a total amount of components.

An antireflective film for a solar cell according to an aspect of the invention includes a translucent binder, wherein the translucent binder contains either one or both of a polymer type binder and a non-polymer type binder, a content of the translucent binder is in a range of 10 parts by mass to 90 parts by mass with respect to 100 parts by mass of a total amount of components, and a refractive index is in a range of 1.70 to 1.90.

In the antireflective film for a solar cell according to the aspect of the present invention, a thickness may be in a range of 0.01 μm to 0.5 μm.

The antireflective film for a solar cell may further include transparent oxide fine particles, wherein the transparent oxide fine particles may be particles of at least one kind selected from a group consisting of SiO₂, TiO₂, ZrO₂, indium tin oxide, ZnO, and antimony tin oxide. A content of the transparent oxide fine particles may be in a range of 10 parts by mass to 90 parts by mass with respect to 100 parts by mass of a total amount of components.

A method for manufacturing an antireflective film for a solar cell according to an aspect of the invention includes: applying the composition for an antireflective film according to the aspect of the present invention onto a transparent conductive film, which is formed on a base material, by a wet coating method to form an antireflective coating film; and subsequently curing the antireflective coating film to form an antireflective film.

In the method for manufacturing an antireflective film for a solar cell according to the aspect of the present invention, the antireflective coating film may be baked at a temperature of 130° C. to 250° C. to be cured.

The wet coating method may be either one of a spray coating method, a dispenser coating method, a spin coating method, a knife coating method, a slit coating method, an inkjet coating method, a die coating method, a screen printing method, an offset printing method, or a gravure printing method.

A solar cell according to an aspect of the invention includes: a substrate; a photoelectric conversion layer which is provided on the substrate; a transparent conductive film or a passivation film which is provided on the photoelectric conversion layer; an antireflective film which is provided on the transparent conductive film or the passivation film; and a sealing material film which is provided on the antireflective film, wherein the antireflective film is the antireflective film according to the aspect of the present invention, and a refractive index n₁ of the transparent conductive film, a refractive index n₂ of the antireflective film, and a refractive index n₃ of the sealing material film satisfy a relational expression of n₁>n₂>n₃.

### Effects of the Invention

In the case where an antireflective film is formed using the composition for an antireflective film according to the aspect of the present invention, the wet coating method can be applied thereto, the antireflective film can be obtained by baking at a low temperature. The refractive index of the antireflective film, which is formed by curing, is in a range of 1.70 to 1.90, and this refractive index is an intermediate value between the refractive index of the transparent conductive film and the refractive index of the sealing material film. Therefore, in the case where the antireflective film is formed using this composition for an antireflective film and this antireflective film is applied to a solar cell, the reflection of light on a surface of the antireflective film and a surface of the transparent conductive film can be suppressed; and thereby, the photoelectric conversion efficiency of the solar cell can be increased.

In the case where the antireflective film according to the aspect of the invention is applied to a solar cell, the reflection of light on the interface between the sealing material film and the antireflective film and the reflection of light on the interface between the antireflective film and the transparent conductive film can be suppressed; and thereby, the photoelectric conversion efficiency can be increased. Therefore, a thin film solar cell with an improved power generation efficiency can be simply obtained.

Here, the antireflective film according to the aspect of the present invention is formed using the composition for an antireflective film according to the aspect of the present invention.

In the method for manufacturing an antireflective film according to the aspect of the present invention, since the wet coating method is applied so as to form an antireflective film, it is not necessary to use a high cost vacuum equipment. In addition, since the antireflective film is formed by baking at a low temperature, the characteristics of semiconductors configuring a photoelectric conversion layer of a solar cell do not deteriorate. Therefore, antireflective films for various kinds of solar cells such as a single crystalline solar cell, a polycrystalline solar cell, a silicon heterojunction solar cell, and substrate type solar cell can be formed. In addition, since the composition for an antireflective film according to the aspect of the present invention is used, an antireflective film can be obtained which can suppress the reflection of light on the interface between the sealing material film and the antireflective film and the reflection of light on the interface between the antireflective film and the transparent conductive film.

In the solar cell according to the aspect of the present invention, the antireflective film according to the aspect of the present invention is provided. Therefore, the reflection of light on the interface between the sealing material film and the antireflective film and the reflection of light on the interface between the antireflective film and the transparent conductive film can be suppressed, and superior power generation efficiency can be achieved. In addition, as described above, since the antireflective film can be formed by the wet coating method, the solar cell can be manufactured at a low cost.

### BRIEF DESCRIPTION OF THE DRAWINGS

FIG. 1 is an example of a schematic cross-sectional view illustrating a silicon heterojunction solar cell which includes an antireflective film according to an embodiment of the present invention.

### BEST MODE FOR CARRYING OUT THE INVENTION

Hereinafter, the present invention will be described in detail based on embodiments of the present invention. The unit “%” indicating a content of a component represents “% by mass” unless specified otherwise.

### [Composition for Antireflective Film]

A composition for an antireflective film for a solar cell according to an embodiment of the present invention contains a translucent binder.

The translucent binder represents a binder which can form a film (thickness: 1 μm) having a transmittance of 80% or higher with respect to light having a wavelength of 550 nm.

The translucent binder contains either one or both of a polymer type binder and a non-polymer type binder. The polymer type binder and the non-polymer-type binder have a property of being cured by heating.

The content of the translucent binder is preferably in a range of 10 parts by mass to 90 parts by mass and more preferably in a range of 30 parts by mass to 80 parts by mass with respect to 100 parts by mass of the composition for an antireflective film other than a dispersion medium (the total amount of components other than a dispersion medium).

In the case where the content of the translucent binder is 10 parts by mass or more, a satisfactory adhesion force to a transparent conductive film can be obtained. In the case where the content of the translucent binder is 90% by mass or less, an antireflective film having a small variation in film thickness can be formed.

Examples of the polymer type binder include acrylic resin, polycarbonate, polyester, alkyd resin, polyurethane, acrylic urethane, polystyrene, polyacetal, polyamide, polyvinyl alcohol, polyvinyl acetate, cellulose, and a siloxane polymer.

It is preferable that the translucent binder contain the polymer type binder and at least one kind selected from a group consisting of a first metal soap, a first metal complex, a first metal alkoxide, and a hydrolysis product of a metal alkoxide. A metal included in the first metal soap, the first metal complex, the first metal alkoxide, and the hydrolysis product of a metal alkoxide is one kind selected from a group consisting of aluminum, silicon, titanium, chromium, manganese, iron, cobalt, nickel, silver, copper, zinc, molybdenum, and tin.

It is preferable that the total content of the first metal soap, the first metal complex, the first metal alkoxide, and the hydrolysis product of a metal alkoxide be in a range of 1 part by mass to 10 parts by mass with respect to 100 parts by mass of the composition for an antireflective film other than a dispersion medium (the total amount of components other than a dispersion medium). By adjusting the content of the first metal soap, the first metal complex, the first metal alkoxide, and the hydrolysis product of a metal alkoxide, the refractive index of the cured antireflective film can be easily controlled to a desired value.

Examples of the non-polymer type binder include a second metal soap, a second metal complex, a second metal alkoxide, alkoxysilane, a halosilane, 2-alkoxyethanol, β-diketone, and alkyl acetate. Each of these compounds can independently function as a binder. Examples of the halosilane include trichlorosilane.

It is preferable that a metal included in the second metal soap, the second metal complex, and the second metal alkoxide be one kind selected from a group consisting of aluminum, silicon, titanium, chromium, manganese, iron, cobalt, nickel, silver, copper, zinc, molybdenum, tin, indium, and antimony. Particularly, it is more preferable that the non-polymer type binder be an alkoxide of silicon or titanium. Examples of the alkoxide of silicon or titanium include tetraethoxysilane, tetramethoxysilane, and butoxysilane.

An antireflective film is formed by applying the composition for an antireflective film according to the embodiment onto a base material and curing the composition. The polymer type binder and the non-polymer type binder are cured by heating; and thereby, an antireflective film having high adhesion can be formed. In addition, by appropriately selecting a compound, which is used as the translucent binder, from among the above-described compound group, the refractive index of the formed antireflective film is set to be in a range of 1.70 to 1.90.

In the case where the translucent binder contains the first metal alkoxide or the second metal alkoxide, it is preferable that the composition for an antireflective film contain water for causing the curing (hydrolysis reaction) of the metal alkoxide to start and either one of an acid or an alkali as a catalyst. Examples of the acid include a hydrochloric acid, a nitric acid, a phosphoric acid (H₃PO₄), and a sulfuric acid. Examples of the alkali include ammonia water and sodium hydroxide. In particular, the nitric acid is more preferable from the viewpoints that it easily volatilizes after being heated and cured and thus it is difficult to remain, that a halogen does not remain, that P (phosphorus) with low water resistance does not remain, and that the adhesion after curing is superior.

In the case where the nitric acid is used as a catalyst, it is preferable that the content of nitric acid be in a range of 1 part by mass to 10 parts by mass with respect to 100 parts by mass of the content of the first and second metal alkoxides. In this case, a favorable curing rate of the translucent binder can be obtained and the remaining amount of the nitric acid can be suppressed at a low level.

In the case where water is contained as a dispersion medium described below, the water of the dispersion medium functions to start the curing (hydrolysis reaction) of the metal alkoxide.

Furthermore, it is preferable that the composition for an antireflective film contain transparent oxide fine particles. In an antireflective film, the transparent oxide fine particles can exert an effect of making light, which is reflected from a transparent conductive film, return to the transparent conductive film side; and thereby, the conversion efficiency of a solar cell can be improved.

It is preferable that the refractive index of the transparent oxide fine particles be in a range of 1.4 to 2.6. In the case where the transparent oxide fine particles have a high refractive index, the refractive index of the cured antireflective film can be easily controlled to a desired value by adjusting the content of the transparent oxide fine particles.

Examples of the transparent oxide fine particles include fine powder of SiO₂, TiO₂, ZrO₂, ITO (Indium Tin Oxide: tin-doped indium oxide), ZnO, ATO (Antimony Tin Oxide: antimony-doped tin oxide), and AZO (Al-containing ZnO). Among these, ITO or TiO₂ is preferable from the viewpoint of refractive index.

The average particle size of the transparent oxide fine particles is preferably in a range of 10 nm to 100 nm and more preferably in a range of 20 nm to 60 nm. In this case, the transparent oxide fine particles can maintain stability in a dispersion medium. Meanwhile, the average particle size is measured by a dynamic light scattering method.

It is preferable that the transparent oxide fine particles be dispersed in a dispersion medium in advance and then the dispersion medium containing the transparent oxide fine particles be mixed with other components of the composition for an antireflective film. Thereby, the transparent oxide fine particles can be evenly dispersed in the composition for an antireflective film.

The content of the transparent oxide fine particles is preferably in a range of 10 parts by mass to 90 parts by mass and more preferably in a range of 20 parts by mass to 70 parts by mass, with respect to 100 parts by mass of the composition for an antireflective film other than a dispersion medium (the total amount of components other than a dispersion medium). In the case where the content of the transparent oxide fine particles is 10 parts by mass or more, an effect of making light, which is reflected from a transparent conductive film, return to the transparent conductive film side can be expected. In the case where the content of the transparent oxide fine particles is 90 parts by mass or less, an antireflective film having sufficient strength can be obtained. In addition, sufficient adhesion strength between an antireflective film and either one of a transparent conductive film or a sealing material film can be obtained.

It is preferable that the translucent binder contain a coupling agent depending on other components. In the case where the coupling agent is included therein, the adhesion (adherence) between a transparent conductive film and an antireflective film and the adhesion (adherence) between an antireflective film and a sealing material film can be improved. In addition, if the transparent oxide fine particles are included, the bond between the transparent oxide fine particles and the translucent binder can be strengthened.

Examples of the coupling agent include a silane coupling agent, an aluminum coupling agent, and a titanium coupling agent.

Examples of the silane coupling agent include vinyl triethoxy silane, γ-glycidoxy propyl trimethoxy silane, and γ-methacryloxy propyl trimethoxy silane.

Examples of the aluminum coupling agent include a compound having an acetoalkoxy group represented by the following formula (1).

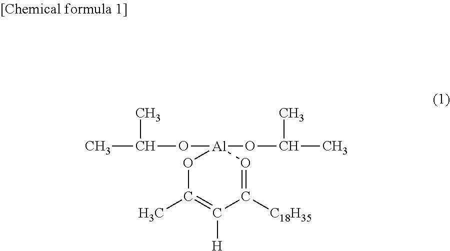

Examples of the titanium coupling agent include compounds having a dialkyl pyrophosphoric acid group represented by the following formulae (2) to (4) and compounds having a dialkyl phosphoric acid group represented by the following formula (5).

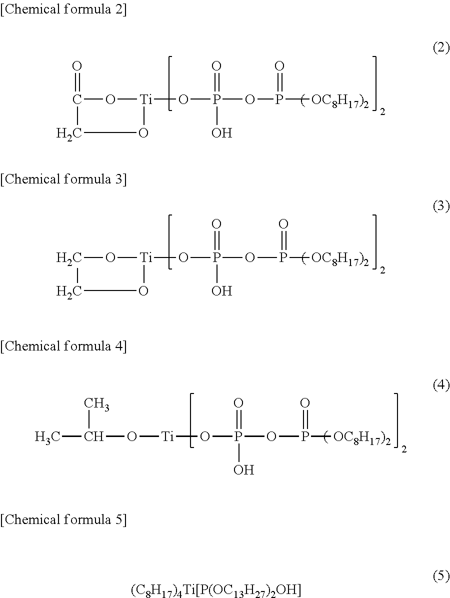

The content of the coupling agent is preferably in a range of 0.01 parts by mass to 5 parts by mass and more preferably in a range of 0.1 parts by mass to 2 parts by mass with respect to 100 parts by mass of the composition for an antireflective film. In the case where the content of the coupling agent is 0.01 parts by mass or more, the adhesion strength between an antireflective film and either one of a transparent conductive film or a sealing material film can be improved. In addition, an effect of greatly improving the dispersibility of the transparent oxide fine particles can be obtained. In the case where the content of the coupling agent is more than 5 parts by mass, unevenness in the film thickness of the formed antireflective film is easily generated.

It is preferable that the composition for an antireflective film contain a dispersion medium. Thereby, a satisfactory antireflective film can be formed. Examples of the dispersion medium include water; alcohols such as methanol, ethanol, isopropyl alcohol, butanol, and the like; ketones such as acetone, methyl ethyl ketone, cyclohexanone, isophorone, and the like; hydrocarbons such as toluene, xylene, hexane, cyclohexane, and the like; amides such as N,N-dimethylformamide, N,N-dimethylacetamide, and the like; sulfoxides such as dimethyl sulfoxide, and the like; glycols such as ethylene glycol, and the like; and glycol ethers such as ethyl cellosolve, and the like.

The content of the dispersion medium is preferably in a range of 80 parts by mass to 99 parts by mass with respect to 100 parts by mass of the composition for an antireflective film. Thereby, a satisfactory antireflective film can be formed.

It is preferable that the composition for an antireflective film contain a water-soluble cellulose derivative depending on components to be used. The water-soluble cellulose derivative is a nonionic surfactant, and even a small amount thereof can exhibit an extremely higher capability of dispersing the transparent oxide fine particles as compared to the other surfactants. In addition, by including the water-soluble cellulose derivative therein, the transparency of an antireflective film can be improved.

Examples of the water-soluble cellulose derivative include hydroxypropyl cellulose and hydroxypropyl methyl cellulose.

The content of the water-soluble cellulose derivative is preferably in a range of 0.2 parts by mass to 5 parts by mass with respect to 100 parts by mass of the composition for an antireflective film.

The translucent binder, the transparent oxide fine particles, and the like are dispersed by mixing the above-described desired components with an ordinary method using a paint shaker, a ball mil, a sand mill, a century mill, a three-roll mil, or the like. Thereby, the composition for an antireflective film can be manufactured. In addition, the composition for an antireflective film can also be manufactured by stirring and mixing the desired components with a normal stirring method.

As described above, in the case where the composition for an antireflective film contains the transparent oxide fine particles, it is preferable that the following method for manufacturing a composition for an antireflective film be applied. The transparent oxide fine particles are dispersed in a dispersion medium in advance. In addition, components other than the transparent oxide fine particles and the dispersion medium are mixed together. Then, the dispersion medium containing the transparent oxide fine particles are mixed with the mixture of the other components. Thereby, a homogeneous composition for an antireflective film can be easily obtained.

### [Antireflective Film]

An antireflective film of a solar cell according to an embodiment of the present invention contains a translucent binder, and the content of the translucent binder is in a range of 10 parts by mass to 90 parts by mass with respect to 100 parts by mass of the antireflective film. In addition, the refractive index of the antireflective film is in a range of 1.70 to 1.90.

The antireflective film according to the embodiment is formed by the curing the above-described composition for an antireflective film according to the embodiment. Therefore, the antireflective film contains the components of the composition for an antireflective film. Generally, the antireflective film is manufactured by applying the composition for an antireflective film onto a base material to form a coating film and drying and baking the coating film to be cured. Therefore, the acid, the alkali, and the dispersion medium are removed by evaporation or decomposition during drying and baking. Such an antireflective film contains the components of the composition for an antireflective film other than the acid, the alkali, and the dispersion medium. The components of the composition for an antireflective film are as described above.

It is preferable that the antireflective film further contain transparent oxide fine particles. The transparent oxide fine particles are particles of at least one kind selected from a group consisting of SiO₂, TiO₂, ZrO₂, indium tin oxide, ZnO, antimony tin oxide, and Al-containing ZnO. It is preferable that the content of the transparent oxide fine particles be in a range of 10 parts by mass to 90 parts by mass with respect to 100 parts by mass of a total amount of components of the antireflective film.

The thickness of the antireflective film is preferably in a range of 0.01 μm to 0.5 μm and more preferably in a range of 0.02 μm to 0.08 μm. In this case, superior adhesion is obtained. In the case where the thickness of the antireflective film is less than 0.01 μm or more than 0.5 μm, an antireflective effect cannot be sufficiently obtained.

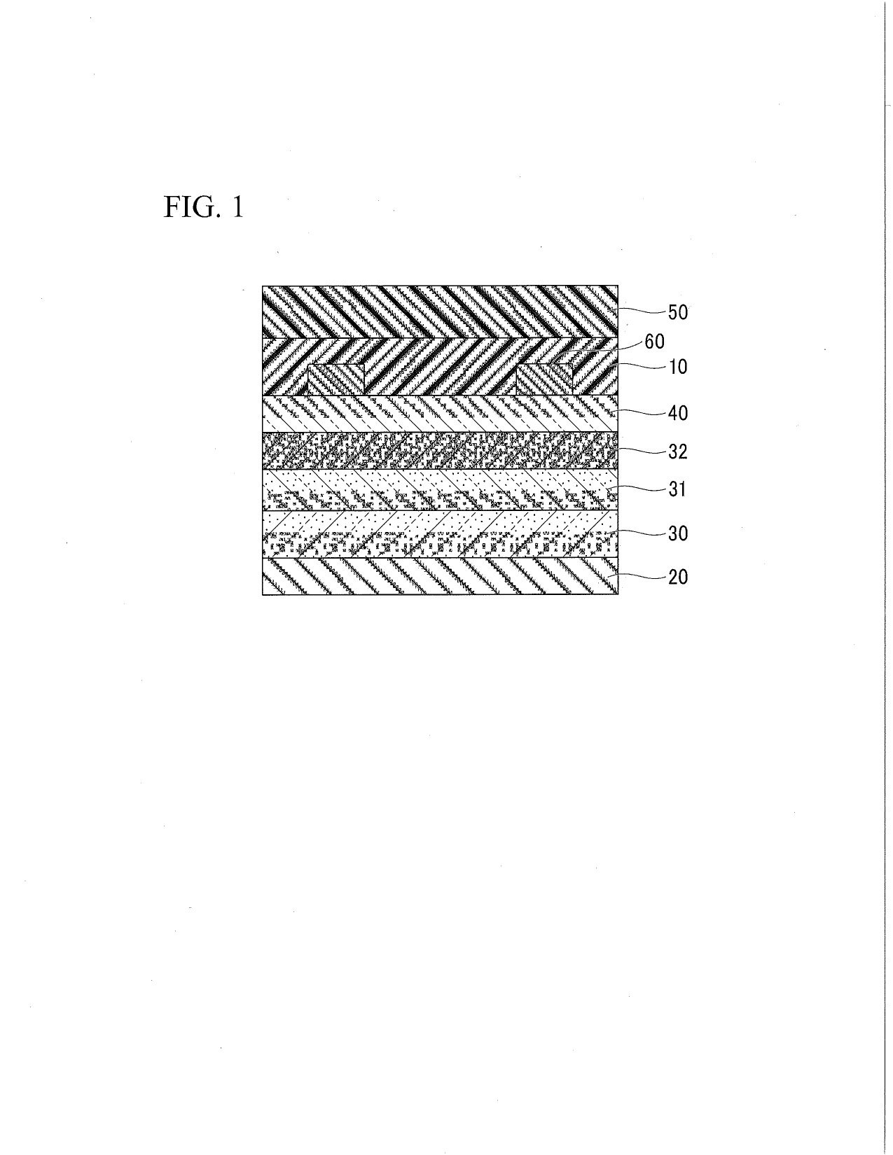

In a solar cell, as illustrated in FIG. 1, a transparent conductive film 40, an antireflective film 10, and a sealing material film 50 are provided in this order on photoelectric conversion layers (an Al layer 20, a single crystalline Si (n-type) substrate 30, an a-Si (i-type) layer 31, and an s-Si (p-type) layer 32). The refractive index of the antireflective film according to the embodiment is in a range of 1.70 to 1.90. Therefore, in the case where the antireflective film according to the embodiment is applied to a solar cell, a refractive index n₁ of the transparent conductive film 40, a refractive index n₂ of the antireflective film 10, and a refractive index n₃ of the sealing material film 50 satisfy a relational expression of n₁>n₂>n₃. Thereby, the reflection of light on a surface of the antireflective film 10 and a surface of the transparent conductive film 40 can be suppressed; and thereby, the photoelectric conversion efficiency of the solar cell can be increased.

### [Method for Manufacturing Antireflective Film]

A method for manufacturing an antireflective film according to an embodiment of the invention includes: a coating process of applying the composition for an antireflective film according to the embodiment onto a transparent conductive film, which is formed on a base material, by a wet coating method to form an antireflective coating film; and a curing process of curing the antireflective coating film to form an antireflective film.

In the coating process, coating conditions are adjusted such that the cured antireflective film has a desired thickness; and thereby, the antireflective coating film is formed. The thickness of the cured antireflective film is preferably in a range of 0.01 μm to 0.5 μm and more preferably in a range of 0.02 μm to 0.08 μm.

The composition for an antireflective film is applied onto the transparent conductive film, and then the coating film is dried to form the antireflective coating film. The drying temperature is in a range of 20° C. to 120° C. and preferably in a range of 25° C. to 60° C. The drying time is in a range of 1 minute to 30 minutes and preferably in a range of 2 minutes to 10 minutes.

The base material includes a substrate and at least photoelectric conversion layers which are provided on the substrate. Examples of the substrate include a glass substrate, a ceramic substrate, a polymer material substrate, a silicon substrate, and a laminate of two or more kinds selected from a group consisting of a glass substrate, a ceramic substrate, a polymer material substrate, and a silicon substrate. The silicon substrate may be a single crystalline silicon substrate or a polycrystalline silicon substrate. Examples of the polymer material substrate include substrates formed from organic polymers such as polyimide, PET (polyethylene terephthalate), or the like.

It is preferable that the above-described wet coating method be any one of a spray coating method, a dispenser coating method, a spin coating method, a knife coating method, a slit coating method, an inkjet coating method, a screen printing method, an offset printing method, and a die coating method. However, the wet coating method is not limited thereto, and various methods can be applied.

In the spray coating method, the composition for an antireflective film is applied onto the base material by converting the composition for an antireflective film into mist through compressed air and applying the mist onto the base material; or by pressurizing the composition for an antireflective film itself to be converted into mist.

In the dispenser coating method, for example, the composition for an antireflective film is applied onto the base material by putting the composition for an antireflective film into a syringe and pushing a piston of the syringe to discharge the composition for an antireflective film from a fine nozzle at a tip of the syringe.

In the spin coating method, the composition for an antireflective film is applied onto the base material by making the composition for an antireflective film fall in drops on the rotating base material; and spreading the drops of the composition for an antireflective film towards the periphery of the base material by the centrifugal force thereof.

In the knife coating method, the composition for an antireflective film is applied onto the base material by providing the substrate at a predetermined interval from a tip of a knife so as to be horizontally movable, supplying the composition for an antireflective film onto the base material, which is located upstream of the knife, and horizontally moving the base material toward the downstream side.

In the slit coating method, the composition for an antireflective film is applied onto the base material by making the composition for an antireflective film flow through a narrow slit.

In the inkjet coating method, an ink cartridge of a commercially available inkjet printer is filled with the composition for an antireflective film to perform inkjet printing on the base material.

In the screen printing method, a gauze is used as a patterning material and the composition for an antireflective film is transferred onto the base material through a printed image formed on the gauze.

In the offset printing method, the composition for an antireflective film, which is attached onto a block, is first transferred onto a rubber sheet from the block without making the composition for an antireflective film directly adhere to the base material, and then is transferred onto the base material from the rubber sheet. The offset printing method is a printing method using the water repellency of the composition for an antireflective film.

In the die coating method, the composition for an antireflective film, which is supplied into a die, is distributed by a manifold and is extruded onto a thin film through a slit so as to be applied onto the base material which travels. Examples of the die coating method include a slot coating method, a slide coating method, and a curtain coating method.

Next, the base material having the antireflective coating film is baked in air or in an inert gas atmosphere such as nitrogen, argon, or the like to cure the antireflective coating film. Thereby, the antireflective film is formed. The baking temperature is preferably in a range of 130° C. to 250° C., more preferably in a range of 180° C. to 220° C., and most preferably in a range of 180° C. to 200° C. The baking time is in a range of 5 minutes to 60 minutes and preferably in a range of 15 minutes to 40 minutes.

In the case where the baking temperature of the antireflective coating film is lower than 130° C., defects such as the insufficient curing of the antireflective film occur. In the case where the baking temperature is higher than 250° C., a production merit of low-temperature process cannot be utilized efficiently. That is, the manufacturing cost increases and the productivity deteriorates. In addition, particularly, amorphous silicon, fine crystalline silicon, or a hybrid silicon solar cell using these materials has relatively low resistance to heat; and therefore, the conversion efficiency deteriorates due to the baking process.

In the case where the baking time of the antireflective coating film is shorter than 5 minutes, defects such as the insufficient curing of the binder occur. In the case where the baking time is longer than 60 minutes, the manufacturing cost increases more than necessary; and therefore, the productivity deteriorates. In addition, the conversion efficiency of a solar cell deteriorates.

In this way, the antireflective film according to the embodiment can be formed. As described above, since the wet coating method is applied to the manufacturing method according to the embodiment, a vacuum process such as a vacuum deposition method or a sputtering method can be excluded as much as possible. Therefore, the antireflective film can be manufactured at a lower cost.

### [Solar Cell]

FIG. 1 illustrates an example of a schematic cross-sectional view illustrating a silicon heterojunction solar cell according to an embodiment of the present invention. The silicon heterojunction solar cell includes the Al layer 20, the single crystal (n-type) 30 as a substrate, the a-Si (i-type) layer 31, the s-Si (p-type) layer 32, the transparent conductive film 40, the antireflective film 10, and the sealing material film 50 in this order. An Ag wiring 60 is formed on the transparent conductive film 40. Sunlight enters from the sealing material film 50 side.

The antireflective film 10 is the above-described antireflective film according to the embodiment. The refractive index n₁ of the transparent conductive film 40, the refractive index n₂ of the antireflective film 10, and the refractive index n₃ of the sealing material film 50 satisfy the relational expression of n₁>n₂>n₃. Thereby, as compared to a case where the s-Si (p-type) layer 32 and the sealing material film 50 are directly laminated, the reflection of incident light between the s-Si (p-type) layer 32 and the sealing material film 50 can be greatly suppressed; and thereby, the power generation efficiency of the solar cell can be improved.

More specifically, the transparent conductive film 40 is generally formed from ITO or ZnO, and the refractive index n₁ thereof is usually in a range of 1.8 to 2.5. The sealing material film 50 is generally formed from EVA (Ethylene Vinyl Acetate), and the refractive index n₃ thereof is usually in a range of 1.5 to 1.6. The refractive index n₂ of the antireflective film 10 is adjusted such that the relational expression of n₁>n₂>n₃ is satisfied in accordance with the refractive index n₁ of the transparent conductive film 40 and the refractive index n₃ of the sealing material film 50. In particular, it is preferable that the refractive index n₂ of the antireflective film 10 satisfy an expression of n₂=(n₁×n₃)^{1/2}.

A passivation film may be provided instead of the transparent conductive film 40. The passivation film is generally formed from SiO₂ or SiN.

Hereinafter, cases of various kinds of solar cells will be described. As the refractive indices, representative values are shown, and the refractive indices only needs to satisfy the relational expression of n₁>n₂>n₃.

In the case of a single crystalline silicon solar cell or a polycrystalline silicon solar cell, the sealing material film formed from EVA having a refractive index of 1.5 to 1.6 or the like, the antireflective film, and the passivation film having a Si surface formed from SiN having a refractive index of 1.8 to 2.5 or the like are positioned in this order from an incident side of sunlight. Therefore, it is preferable that the refractive index of the antireflective film be about 1.7.

In the case of a silicon heterojunction solar cell, the sealing material film formed from EVA having a refractive index of 1.5 to 1.6, the antireflective film, and the transparent conductive film having a refractive index of 2.0 are positioned in this order from an incident side of sunlight. Therefore, it is preferable that the refractive index of the antireflective film be about 1.8.

In the case of a substrate type thin film solar cell, the sealing material film formed from EVA having a refractive index of 1.5 to 1.6, the antireflective film, and the transparent conductive film having a refractive index of 2.0 are positioned in this order from an incident side of sunlight. Therefore, it is preferable that the refractive index of the antireflective film be about 1.8.

In addition, it is preferable that two or more layers of antireflective films be provided. In this case, it is preferable that the antireflective films be formed such that the refractive indices of the antireflective films gradually decrease from the transparent conductive film toward the sealing material film.

### EXAMPLES

Hereinafter, the embodiments will be described using Examples, but the embodiments are not limited thereto.

First, a SiO₂ binder used as a binder was manufactured according to the following method. 11.0 g of HCl (concentration: 12 mol/l) was dissolved in 25 g of pure water to prepare an aqueous HCl solution. Using a four-necked 500 cm³ flask made of glass, 140 g of tetraethoxysilane and 240 g of ethyl alcohol were mixed. While stirring this mixture, the aqueous HCl water was added thereto at a time. Then, a reaction was conducted at 80° C. for 6 hours to prepare a SiO₂ binder. This SiO₂ binder is a polymer of silicon alkoxide and is a non-polymer type binder.

Each of mixtures having compositions (numerical values are represented in terms of parts by mass) shown in Tables 1 and 2 was prepared. 60 g of the mixture and 100 g of zirconia beads (MICROHICA, manufactured by Showa Shell Sekiyu K.K.) having a diameter of 0.3 mm were put into a 100 cm³ glass bottle. The glass bottle was repeatedly rotated for 6 hours using a paint shaker so as to disperse transparent conductive particles (transparent oxide fine particles), which were present in the mixture, in the binder. In this way, compositions for antireflective films 1 to 10 were prepared.

Titanium agents (1), (2), (3), (4), and (5) shown in the item “Coupling Agent” of Tables 1 and 2 represent the above-described titanium coupling agents represented by the formulae (1), (2), (3), (4), and (5), respectively.

TABLE 1

| | | |
|---|---|---|
| | | Parts |
| Classification | Name | by mass |

Sample No. 1

| | | |
|---|---|---|
| Non-Polymer Type Binder | 2-N-Butoxyethanol | 4 |
| | 3-Isopropyl-2,4-Pentanedione | 2 |
| Polymer Type Binder | | 0 |
| Transparent Conductive | ITO Particles (In:Sn = 90:10), | 4 |
| Particles | Average Particle Size: 20 nm | |
| Coupling Agent | | 0 |
| Dispersion Medium | Isopropanol | 90 |

Sample No. 2

| | | |
|---|---|---|
| Non-Polymer Type Binder | 2,4-Pentanedione | 2 |
| Polymer Type Binder | | 0 |
| Transparent Conductive | ZnO Particles, | 7.8 |
| Particles | Average Particle Size: 10 nm | |
| Coupling Agent | Titanium Agent (4) | 0.2 |
| Dispersion Medium | Ethanol | 90 |

Sample No. 3

| | | |
|---|---|---|
| Non-Polymer Type Binder | 2-N-Propoxyethanol | 5 |
| Polymer Type Binder | | 0 |
| Transparent Conductive | TiO₂ Particles, | 4.8 |
| Particles | Average Particle Size: 50 nm | |
| Coupling Agent | Titanium Agent (4) | 0.2 |
| Dispersion Medium | Isopropanol | 90 |

Sample No. 4

| | | |
|---|---|---|
| Non-Polymer Type Binder | 2,2-Dimethyl-3,5-Hexanedione | 3 |
| | Isopropyl Acetate | 3 |
| Polymer Type Binder | | 0 |
| Transparent Conductive | TiO₂ Particles, | 3.8 |
| Particles | Average Particle Size: 50 nm | |
| Coupling Agent | Titanium Agent (3) | 0.2 |
| Dispersion Medium | Isopropanol | 90 |

Sample No. 5

| | | |
|---|---|---|
| Non-Polymer Type Binder | 2-Hexyloxyethanol | 4 |
| | N-Propyl Acetate | 3 |
| Polymer Type Binder | | 0 |
| Transparent Conductive | ZrO₂ Particles, | 2.8 |
| Particles | Average Particle Size: 70 nm | |
| Coupling Agent | Titanium Agent (5) | 0.2 |
| Dispersion Medium | Isopropanol | 90 |

TABLE 2

| | | |
|---|---|---|
| | | Parts |
| Classification | Name | by mass |

Sample No. 6

| | | |
|---|---|---|
| Non-Polymer Type Binder | 2-Hexyloxyethanol | 5 |
| | N-Propyl Acetate | 2.5 |
| Polymer Type Binder | Hydroxypropyl Cellulose | 0.5 |
| Transparent Conductive | ZnO Particles, | 2 |
| Particles | Average Particle Size: 10 nm | |
| Coupling Agent | | 0 |
| Dispersion Medium | Isopropanol | 90 |

Sample No. 7

| | | |
|---|---|---|
| Non-Polymer Type Binder | SiO₂ Binder | 7.5 |
| Polymer Type Binder | | 0 |
| Transparent Conductive | AZO Particles, | 2.3 |
| Particles | Average Particle Size: 20 nm | |
| Coupling Agent | Titanium Agent (3) | 0.2 |
| Dispersion Medium | Butanol | 90 |

Sample No. 8

| | | |
|---|---|---|
| Non-Polymer Type Binder | SiO₂ Binder | 1.7 |
| Polymer Type Binder | | 0 |
| Transparent Conductive | TiO₂ Particles, | 7.8 |
| Particles | Average Particle Size: 50 nm | |
| Coupling Agent | Titanium Agent (2) | 0.5 |
| Dispersion Medium | Butanol | 90 |

Sample No. 9

| | | |
|---|---|---|
| Non-Polymer Type Binder | SiO₂ Binder | 10.0 |
| Polymer Type Binder | | 0 |
| Transparent Conductive | | 0.0 |
| Particles | | |
| Coupling Agent | | 0.0 |
| Dispersion Medium | Butanol | 90 |

Sample No. 10

| | | |
|---|---|---|
| Non-Polymer Type Binder | 2,4-Pentanedione | 1 |
| Polymer Type Binder | | 0 |
| Transparent Conductive | ZrO₂ Particles, | 7.8 |
| Particles | Average Particle Size: 10 nm | |
| Coupling Agent | Titanium Agent (1) | 0.2 |
| Dispersion Medium | Butanol | 90 |

Each of the compositions for antireflective films 1 to 10 was applied onto an alkali glass having a thickness of 1 mm to prepare a coating film. Next, the coating film was baked in air under conditions shown in Table 3 to prepare an antireflective film. The transmittance of the antireflective film at a wavelength of 600 nm was measured using an UV-Vis Spectrophotometer. At this time, the transmittance of the substrate was excluded as a background. In addition, the refractive index of the antireflective film was measured using an ellipsometer. The obtained results are shown in Table 3.

TABLE 3

| | Example 1 | Example 2 | Example 3 | Example 4 | Example 5 |
|---|---|---|---|---|---|
| Sample No. | 1 | 2 | 3 | 4 | 5 |
| Thickness (nm) of | 100 | 10 | 100 | 300 | 500 |
| Antireflective Film | | | | | |
| Refractive Index of | 1.78 | 1.90 | 1.85 | 1.84 | 1.88 |
| Antireflective Film | | | | | |
| Transmittance (%) | 90 | 96 | 90 | 85 | 82 |
| (600 nm) | | | | | |
| Film-Forming | Spray Coating | Spin Coating | Knife Coating | Slit Coating | Dispenser Coating |
| Method | Method | Method | Method | Method | Method |
| Baking Conditions | 130° C.-60 | 140° C.-60 | 130° C.-30 | 150° C.-20 | 180° C.-10 |
| | Minutes | Minutes | Minutes | Minutes | Minutes |

| | | | | Comparative | Comparative |
|---|---|---|---|---|---|
| | Example 6 | Example 7 | Example 8 | Example 1 | Example 2 |
| Sample No. | 6 | 7 | 8 | 9 | 10 |
| Thickness (nm) of | 200 | 100 | 100 | 200 | 300 |
| Antireflective Film | | | | | |
| Refractive Index of | 1.75 | 1.74 | 1.85 | 1.42 | 2.10 |
| Antireflective Film | | | | | |
| Transmittance (%) | 88 | 94 | 92 | 78 | 75 |
| (600 nm) | | | | | |
| Film-Forming | Die Coating | Spin Coating | Spin Coating | Spin Coating | Spin Coating |
| Method | Method | Method | Method | Method | Method |
| Baking Conditions | 170° C.-30 | 200° C.-30 | 250° C.-10 | 200° C.-10 | 200° C.-10 |
| | Minutes | Minutes | Minutes | Minutes | Minutes |

As clearly seen from Table 3, the refractive indices of all the antireflective films of Examples 1 to 8 were within a desired range of 1.74 to 1.90. Therefore, in the case where the antireflective films of Examples 1 to 8 are applied to various kinds of solar cells, the refractive index n₁ of the transparent conductive film, the refractive index n₂ of the antireflective film, and the refractive index n₃ of the sealing material film can satisfy the relational expression of n₁>n₂>n₃. In addition, the transmittances were in a range of 82% to 94% which were satisfactory results.

On the other hand, in the antireflective film of Comparative Example 1, the refractive index was low and the transmittance was 78% which was low. In addition, in the antireflective film of Comparative Example 2, the transmittance was 75% which was also low.

### INDUSTRIAL APPLICABILITY

The composition for an antireflective film according to the embodiment is applied onto the transparent conductive film by the wet coating method, and the coating film is baked; and as a result, an antireflective film can be formed. In the case where the obtained antireflective film is applied to a solar cell, the reflection of light on the interface between the sealing material film and the antireflective film and the reflection of light on the interface between the antireflective film and the transparent conductive film can be suppressed. As a result, the photoelectric conversion efficiency can be improved. Therefore, the composition for an antireflective film according to the embodiment can be desirably applied to processes for manufacturing various kinds of solar cells.

### BRIEF DESCRIPTION OF REFERENCE SIGNS

10 antireflective film
20 Al layer
30 single crystal (n type)
31 a-Si (i type)
32 s-Si (p type)
40 transparent conductive film
50 sealing material film
60 Ag wiring

1. A composition for an antireflective film for a solar cell comprising:
a translucent binder,
wherein the translucent binder contains either one or both of a polymer type binder and a non-polymer type binder,
a content of the translucent binder is in a range of 10 parts by mass to 90 parts by mass with respect to 100 parts by mass of a total amount of components other than a dispersion medium, and
a refractive index of an antireflective film which is formed by curing the composition for an antireflective film is in a range of 1.70 to 1.90.

2. The composition for an antireflective film for a solar cell according to claim 1,
wherein the polymer type binder is at least one kind selected from a group consisting of acrylic resin, polycarbonate, polyester, alkyd resin, polyurethane, acrylic urethane, polystyrene, polyacetal, polyamide, polyvinyl alcohol, polyvinyl acetate, cellulose, and a siloxane polymer.

3. The composition for an antireflective film for a solar cell according to claim 2,
wherein the translucent binder contains the polymer type binder and at least one kind selected from a group consisting of a first metal soap, a first metal complex, a first metal alkoxide, and a hydrolysis product of a metal alkoxide, and
a metal included in the first metal soap, the first metal complex, the first metal alkoxide, and the hydrolysis product of a metal alkoxide is one kind selected from a group consisting of aluminum, silicon, titanium, chromium, manganese, iron, cobalt, nickel, silver, copper, zinc, molybdenum, and tin.

4. The composition for an antireflective film for a solar cell according to claim 1,
wherein the non-polymer type binder is at least one kind selected from a group consisting of a second metal soap, a second metal complex, a second metal alkoxide, alkoxysilane, a halosilane, 2-alkoxyethanol, β-diketone, and alkyl acetate.

5. The composition for an antireflective film for a solar cell according to claim 4,
wherein a metal included in the second metal soap, the second metal complex, and the second metal alkoxide is one kind selected from a group consisting of aluminum, silicon, titanium, chromium, manganese, iron, cobalt, nickel, silver, copper, zinc, molybdenum, tin, indium, and antimony.

6. The composition for an antireflective film for a solar cell according to claim 5,
wherein the non-polymer type binder is a metal alkoxide of silicon or titanium.

7. The composition for an antireflective film for a solar cell according to claim 1, further comprising:
transparent oxide fine particles,
wherein a content of the transparent oxide fine particles is in a range of 10 parts by mass to 90 parts by mass with respect to 100 parts by mass of a total amount of components other than a dispersion medium.

8. The composition for an antireflective film for a solar cell according to claim 7,
wherein the transparent oxide fine particles are particles of at least one kind selected from a group consisting of SiO₂, TiO₂, ZrO₂, indium tin oxide, ZnO, antimony tin oxide, and Al-containing ZnO.

9. The composition for an antireflective film for a solar cell according to claim 7,
wherein an average particle size of the transparent oxide fine particles is in a range of 10 nm to 100 nm.

10. The composition for an antireflective film for a solar cell according to claim 1, further comprising:
a coupling agent,
wherein the coupling agent is one kind selected from a group consisting of vinyl triethoxy silane, γ-glycidoxy propyl trimethoxy silane, γ-methacryloxy propyl trimethoxy silane, an aluminum coupling agent having an acetoalkoxy group, a titanium coupling agent having a dialkyl pyrophosphoric acid group, and a titanium coupling agent having a dialkyl phosphoric acid group, and
a content of the coupling agent is in a range of 0.01 parts by mass to 5 parts by mass with respect to 100 parts by mass of a total amount of components.

11. The composition for an antireflective film for a solar cell according to claim 1, further comprising:
a dispersion medium,
wherein the dispersion medium is at least one kind selected from a group consisting of water, methanol, ethanol, isopropyl alcohol, butanol, acetone, methyl ethyl ketone, cyclohexanone, isophorone, toluene, xylene, hexane, cyclohexane, N,N-dimethylformamide, N,N-dimethylacetamide, dimethyl sulfoxide, ethylene glycol, and ethyl cellosolve, and
a content of the dispersion medium is in a range of 80 parts by mass to 99 parts by mass with respect to 100 parts by mass of a total amount of components.

12. The composition for an antireflective film for a solar cell according to claim 1, further comprising:
a water-soluble cellulose derivative,
wherein the water-soluble cellulose derivative is hydroxypropyl cellulose or hydroxypropyl methyl cellulose, and
a content of the water-soluble cellulose derivative is in a range of 0.2 parts by mass to 5 parts by mass with respect to 100 parts by mass of a total amount of components.

13. An antireflective film for a solar cell comprising:
a translucent binder,
wherein the translucent binder contains either one or both of a polymer type binder and a non-polymer type binder,
a content of the translucent binder is in a range of 10 parts by mass to 90 parts by mass with respect to 100 parts by mass of a total amount of components, and
a refractive index is in a range of 1.70 to 1.90.

14. The antireflective film for a solar cell according to claim 13,
wherein a thickness is in a range of 0.01 μm to 0.5 μm.

15. The antireflective film for a solar cell according to claim 13, further comprising:
transparent oxide fine particles,
wherein the transparent oxide fine particles are particles of at least one kind selected from a group consisting of SiO₂, TiO₂, ZrO₂, indium tin oxide, ZnO, antimony tin oxide, and Al-containing ZnO, and
a content of the transparent oxide fine particles is 10 parts by mass to 90 parts by mass with respect to 100 parts by mass of a total amount of components.

16. A method for manufacturing an antireflective film for a solar cell, comprising:
applying the composition for an antireflective film according to claim 1 onto a transparent conductive film, which is formed on a base material, by a wet coating method to form an antireflective coating film; and
subsequently curing the antireflective coating film to form an antireflective film.

17. The method for manufacturing an antireflective film for a solar cell according to claim 16,
wherein the antireflective coating film is baked at a temperature of 130° C. to 250° C. to be cured.

18. The method for manufacturing an antireflective film for a solar cell according to claim 16,
wherein the wet coating method is either one of a spray coating method, a dispenser coating method, a spin coating method, a knife coating method, a slit coating method, an inkjet coating method, a die coating method, a screen printing method, an offset printing method, or a gravure printing method.

19. A solar cell comprising:
a substrate;
a photoelectric conversion layer which is provided on the substrate;
a transparent conductive film or a passivation film which is provided on the photoelectric conversion layer;
an antireflective film which is provided on the transparent conductive film or the passivation film; and
a sealing material film which is provided on the antireflective film,
wherein the antireflective film is the antireflective film according to claim 13, and
a refractive index n₁ of the transparent conductive film, a refractive index n₂ of the antireflective film, and a refractive index n₃ of the sealing material film satisfy a relational expression of n₁>n₂>n₃.
